(19) United States
(12) Patent Application Publication
(10) Pub. No.: US 2009/0304490 A1
(43) Pub. Date: Dec. 10, 2009

(54) METHOD FOR HOLDING SILICON WAFER

(76) Inventors: Takayuki Kihara, Tokyo (JP); Masataka Hourai, Tokyo (JP); Yuki Murata, Tokyo (JP); Kazushige Takaishi, Tokyo (JP); Seiji Sugimoto, Tokyo (JP); Tadashi Kanda, Tokyo (JP)

Correspondence Address: BRINKS HOFER GILSON & LIONE, P.O. BOX 10395, CHICAGO, IL, 60610, US

(21) Appl. No.: 12/135,805

(22) Filed: Jun. 9, 2008

(51) Int. Cl. H01L 21/67

(52) U.S. Cl. 414/800

(57) ABSTRACT

The present invention is directed to provide a method for holding a silicon wafer, which can reduce contact scratches in contact with support members when holding a back surface of the silicon wafer, as well as prevent the wafer from bending when holding the back surface of the silicon wafer. The back surface of a silicon wafer of 300 millimeters or more in diameter and 700 micrometers to 1000 micrometers in thickness is held in contact with a support member or a suction member, specifically held within a region where a radius of the silicon wafer×0.50 to 0.80 from a center thereof. The silicon wafer is held in a state where the maximum amount of displacement within a wafer plane is 300 micrometers or less. The silicon wafer back surface is held in contact within the holding region in all the processes of holding the back surface of the silicon wafer in contact with the support member or the suction member.

### BACKGROUND OF THE INVENTION

1. Field of the Invention

The present invention relates to a method for holding a silicon wafer upon processing the same while holding the back surface of the silicon wafer in contact with a support member or a suction member.

2. Description of the Related Art

In each process of manufacturing silicon wafers, there are many processes upon processing the same while holding the back surface of the silicon wafer in contact with a support member or a suction member. For example, in a transportation process of the silicon wafer or many heat treatment processes, such as a heat treatment process using a vertical boat, an RTA (Rapid Thermal Annealing) process, a single wafer epitaxial growth process, and a SOI heat treatment process, various processes are performed in a state where the back surface of the silicon wafer is held in contact with the support member or the suction member.

Particularly, in the transportation process of the silicon wafer, a heat treatment apparatus, an epitaxial apparatus, or the like in which next-generation wafer containers, such as FOUP (Front Open Unified Pod) compliant with the SEMI standard are arranged is frequently used in recent years, and wafer transportation between the container and the apparatus is performed in a narrow and limited space region, and thus when wafer transportation is performed while holding the wafer back surface in contact with the support member or the suction member, careful attention must be increasingly paid so that the wafer and components within the apparatus may not be contacted with each other.

Meanwhile, it is reported to hold only the periphery of the silicon wafer (edge handling) instead of holding the back surface of the wafer with the suction member or the like as described in Japanese Unexamined Patent Application Publication No. 2002-33378.

Until now, in the transportation of the silicon wafer of 200 millimeters or less in diameter, there has not been occurred a problem that the wafer bends due to its own weight during the transportation since the diameter of the wafer is also small, and holding the wafer back surface with the suction member has been mainly performed due to handling easiness, but the wafer diameter has been increasingly larger in recent years, so that the wafer is likely to bend when the silicon wafers of 300 millimeters or more, especially 450 millimeters in diameter are transported while holding the back surfaces thereof. In addition to that, as for positions to hold the back surface of the wafer, since the wafer back surface positions arbitrarily set by silicon wafer manufacturers, semiconductor device manufacturers, and device manufacturers have been held, respectively, various positions in the back surface of single silicon wafer are held contiguously in each process, and thus contact scratches with the suction member or the like have been formed in various portions in the wafer back surface to thereby induce particle deposition due to the contact scratches, so that there have been problems to cause harmful effects such that steps have been formed on the wafer surface upon using lithography which would be performed in the following device process.

Since further miniaturized-generation devices will be manufactured using the silicon wafer of 300 millimeters or more, especially 450 millimeters in diameter in the future, the contact scratches due to the contact between the wafer back surface and the suction member or the like need to be reduced as much as possible, so that employing the edge handling of the silicon wafer is becoming unavoidable.

However, when the edge handling of the large wafer of 300 millimeters or more in diameter is performed, there may occur a problem that the wafer greatly bends due to its own weight. When the edge handling especially of the silicon wafer of 450 millimeters in diameter is performed, amount of displacement caused by the wafer own weight at room temperature results in around 1 millimeter, and thus a temperature difference in the wafer surface is increased when transporting the hot silicon wafer after finishing a thermal process, so that further wafer deformation may occur. For this reason, the bent wafer may contact with the components within the apparatus, the container, or the like to thereby cause metal contamination, scratches, cracks, or the like, resulting in a problem of an increase in size of the apparatus in order to solve this. Additionally, the edge handling of the wafer with a large diameter is very unstable in holding the wafer, so that there is a problem that the wafer may be dropped during the wafer transportation. Furthermore, when the contact scratch is caused on the edge portion by the edge handling, there also occurs a problem that slip dislocation or the like is generated from the periphery of the wafer to the center thereof starting from it.

### SUMMARY OF THE INVENTION

It is an object of the present invention to provide a method for holding a silicon wafer, which can reduce an amount of displacement of the wafer, causes few troubles in transporting the wafer, and suppresses generation of slip even when heat treatment is performed in each process.

In order to achieve the above object, the inventor pays attention to a relation between a holding position of a silicon wafer back surface and an amount of displacement within a wafer plane, and then earnestly examines it to complete the present invention.

The present invention is characterized in that a back surface of a silicon wafer of 300 millimeters or more in diameter and 700 micrometers to 1000 micrometers in thickness is held in contact with a support member or a suction member, specifically held within a region where a radius of the silicon wafer×0.50 to 0.80 from a center thereof.

The present invention is characterized in that the back surface of the silicon wafer is held in a state where the maximum amount of displacement within the wafer plane is 300 micrometers or less. Here, the maximum amount of displacement within the wafer plane is a value calculated on the assumption that the wafer is kept at room temperature using a finite element method.

The present invention is characterized in that the silicon wafer back surface is held in contact within the above described region in all the processes of holding the back surface of the silicon wafer in contact with the support member or the suction member.

According to the present invention, since a specific region in the wafer back surface set so that the maximum amount of displacement within the wafer plane may be very small is held with the support member or the suction member even in the large wafer of 300 millimeters or more, especially 450 millimeters in diameter, the problem of such a wafer bend formed in performing edge handling of the wafer with a large diameter can be solved. Namely, it is possible to prevent secondary adverse effects, such as metal contamination, scratches, and cracks caused by the bent wafer contacting with the components in the apparatus or the like, thereby allowing high-quality silicon wafers to be manufactured. At the same time, it is not required to increase the size of the apparatus in consideration of the wafer bend and transportation speed is also improved, thus resulting in a contribution to a reduction in production cost.

### BRIEF DESCRIPTION OF THE DRAWINGS

FIG. 1 is a schematic view showing a wafer back surface holding region according to an embodiment of the present invention;

FIG. 2 is a schematic view showing a wafer holding member preferably used for a holding method of the present invention;

FIGS. 3(A), 3(B), 3(C), 3(D), and 3(E) are schematic views showing various wafer supporting members whose wafer displacement amount is investigated according to an example of the present invention; and

FIG. 4 is a graph showing the wafer displacement amount of various wafer supporting members according to the example of the present invention.

### DETAILED DESCRIPTION OF THE PREFERRED EMBODIMENTS

A method for holding a silicon wafer according to the present invention is the one that a back surface of a silicon wafer of 300 millimeters or more in diameter and 700 micrometers to 1000 micrometers in thickness is held in contact with a support member or a suction member and then performed processing, the silicon wafer is held in contact within a region where a radius of the silicon wafer (r)×0.5 r to 0.8 r from a center thereof. FIG. 1 is a schematic view showing a wafer back surface holding region according to the present invention. By holding the wafer within the limits of a back surface holding region 2 in a wafer 1, the maximum amount of displacement within the wafer plane can be reduced as much as possible. If the wafer is held in the holding region less than 0.5 r, it is liable to bend in a periphery thereof and if in the holding region of more than 0.8 r, it bends in a center thereof. However, even if the wafer is held in the holding region specified by the present invention, the amount of displacement substantially increases in a case where a thickness of the silicon wafer is less than 700 micrometers and therefore the thicker the wafer is, the more preferred, however, considering a manufacturing cost, desired thickness of the wafer is 1000 micrometers or less.

The method for holding a silicon wafer according to the present invention is a method for holding the wafer in a state where the maximum amount of displacement within the wafer plane is 300 micrometers or less. The amount of displacement of the wafer differs depending on a thermal environment thereof and the larger a temperature difference in the wafer surface, the more increases the amount of displacement. Although the maximum amount of displacement within the wafer plane specified by the present invention is calculated on the assumption that the wafer is kept in a room temperature, as long as the amount of displacement falls in the one specified by the present invention, even in a thermal environment process of 1000 degrees C. or more, the wafer does not bend.

The method for holding a silicon wafer according to the present invention is the one that in all the processes of holding the back surface of the silicon wafer in contact with the support member or the suction member, the silicon wafer back surface is held in contact within the above described region. According to the present invention, since the silicon wafer is held in the back surface thereof, there is a concern that holding the wafer back surface in contact with a support member forms scratches, however, by contiguously holding the same region as in all the processes of holding the back surface of the wafer, contact scratches are formed only in the limited and specific region, thus resulting the minimum scratches or particle deposition caused by back surface chuck. In particular, by standardizing a method that the wafer is held in the ring-shaped minimum region specified by the present invention by each of wafer manufacturers, semiconductor device manufacturers, and device manufacturers, respectively, the contact scratches are formed in the limited and more specific region, thus allowing the scratches or particle deposition caused by the back surface chuck to be reduced as much as possible. In addition, according to the present invention, since the contact scratches are formed in the specific region, if the wafer is held so that only the region where contact scratches are formed may not be held with a pin chuck or the like when using lithography by a device, steps are not formed in the region where the contact scratches are formed and therefore there is no harmful effect on pattern formation onto the wafer surface.

The processes of contiguously holding the back surface of the wafer to which the present invention is directed include a wafer transportation process between each process, a transportation process between a wafer container and a heat treatment apparatus, a heat treatment process using a vertical boat, a RTA heat treatment process, an oxidation heat treatment process, a single wafer epitaxial growth process, an SOI heat treatment process, a SIMOX heat treatment process, a container, or the like, but not limited to these processes, in all the processes of performing processing of the silicon wafer while holding the back surface thereof in contact with the support member or the suction member, the holding method according to the present invention is applicable. The method is effective especially in the process of performing processing while maintaining the silicon wafer at a horizontal state.

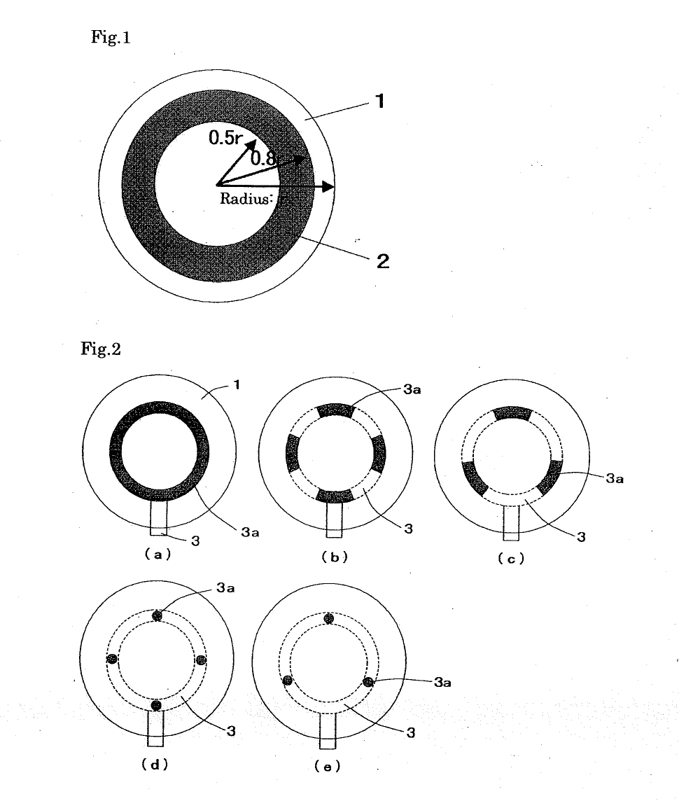

FIG. 2 is a schematic view showing a preferred embodiment of the suction member that holds in contact with the holding region specified in the present invention. All the FIGS. 2(A) to (E) are used when the back surface of the wafer 1 is sucked and held (chucking) with a suction portion 3a provided in a suction member 3 and the shapes are preferably a structure with which the wafer is supported or sucked in the direction of the periphery thereof, such as a ring (FIG. 2(A)), circle (FIGS. 2(B), (C)), and a point support (FIG. 2(D), (E)), while desired materials as the suction member and the support member include quartz, single crystal silicon, polycrystalline silicon, silicon carbide, silicon impregnating silicon carbide, or the like. Which shape or which material is employed may be determined arbitrarily according to a thermal environment of a target process.

### EXAMPLE

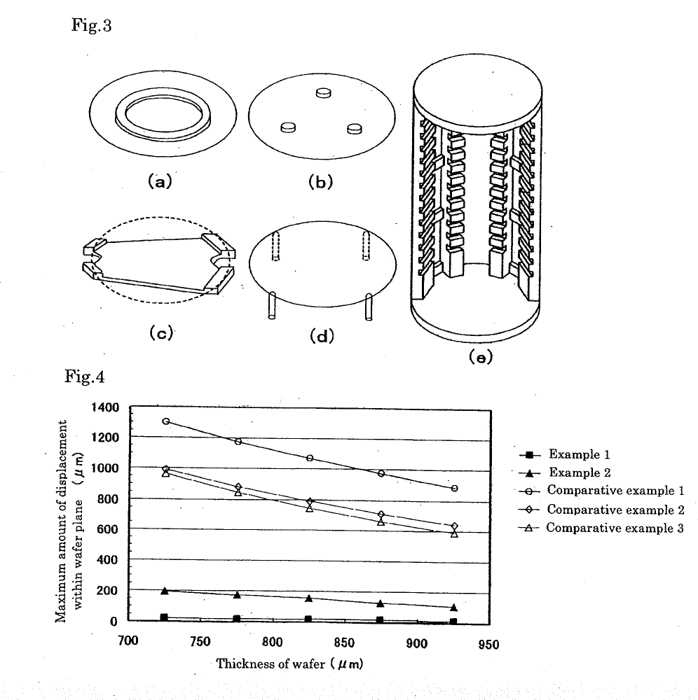

Examples according to the present invention will be described below. With respect to support member shapes shown in FIGS. 3(A) to (E), respectively, how much maximum amount of displacement in a wafer surface changes depending on a holding position in a silicon wafer of 450 millimeters in diameter and a thickness thereof was investigated using a finite element method. The result is shown in FIG. 4.

FIG. 3 (A) is a ring-shaped support member which supports a region of 0.65 r to 0.70 r of a wafer radius (r) as an example 1 according to the present invention, FIG. 3 (B) is a support member which supports three points in a region of 0.65 r of a wafer radius (r) as an example 2 according to the present invention, FIG. 3 (C) is a wafer transporting blade (supporting four points in the periphery) used within an epitaxial growth system as a comparative example 1, FIG. 3 (D) is a holder (supporting four points in the periphery) which standby holds a wafer in a load lock chamber of an epitaxial growth system as a comparative example 2, and FIG. 3 (E) is a vertical heat treatment boat (supporting four points in the periphery) as a comparative example 3.

As is apparent in FIG. 4, all the maximum amount of displacement according to the examples 1 and 2 wherein the wafer is held within the wafer back surface holding region specified by the present invention were 200 micrometers or less, in the case of three-point support or ring support, substantial reduction effect was confirmed.

According to the method for holding a silicon wafer of the present invention, even if the back surface of the large wafer of 300 millimeters or more in diameter is held, since the maximum amount of displacement within the wafer plane is very small, the wafer does not bend, and therefore secondary adverse effects, such as metal contamination, scratches, and cracks caused by the bent wafer's contacting with components in an apparatus or the like, can be prevented. At the same time, the apparatus is not required to be larger size and transportation speed is also improved, thus allowing the wafers to be manufactured at low cost. For this reason, the silicon wafer held with the method according to the present invention is inexpensive and functions effectively as the wafer which does not cause device property deterioration.

What is claimed is:

1. A method for holding a silicon wafer, wherein a back surface of a silicon wafer of 300 millimeters or more in diameter and 700 micrometers to 1000 micrometers in thickness is held in contact with a support member or a suction member, specifically held within a region where a radius of the silicon wafer×0.50 to 0.80 from the center thereof.

2. The method for holding a silicon wafer according to claim 1, wherein the silicon wafer is held in a state where the maximum amount of displacement within a wafer plane is 300 micrometers or less.

3. The method for holding a silicon wafer according to claim 1, wherein the silicon wafer back surface is held in contact within the holding region in all the processes of holding the back surface of the silicon wafer in contact with the support member or the suction member.

4. The method for holding a silicon wafer according to claim 2, wherein the silicon wafer back surface is held in contact within the holding region in all the processes of holding the back surface of the silicon wafer in contact with the support member or the suction member.
